(19) United States
(12) Patent Application Publication
(10) Pub. No.: US 2026/0088482 A1
(43) Pub. Date: Mar. 26, 2026

(54) TUNABLE WAVEGUIDE ATTENUATOR AND MEASUREMENT SETUP

(71) Applicant: Rohde & Schwarz GmbH & Co. KG, München (DE)

(72) Inventors: Josef SCHMOELLER, Windorf (DE); Christoph TOBEN-HEIKEN, München (DE); Robert KROGLER, Pfaffing (DE); Christoph HAMMERL, München (DE); Andreas RAITH, Prackenbach (DE)

(21) Appl. No.: 18/895,807

(22) Filed: Sep. 25, 2024

(51) Int. Cl. H01P 1/22; H01P 1/12; H01P 1/30; H01P 3/127; H01P 11/00

(52) U.S. Cl. CPC H01P 1/222; H01P 1/122; H01P 1/30; H01P 3/127; H01P 11/002

(57) ABSTRACT

The present disclosure provides a tunable waveguide attenuator comprising a base structure with a bottom wall, a first side wall, and a second side wall, wherein the first side wall and the second side wall are arranged on opposite sides of the bottom wall, and wherein the bottom wall, the first side wall, and the second side wall enclose a hollow waveguide channel on three sides. The tunable waveguide attenuator further comprises a movable cover for the hollow waveguide channel that on a surface facing the bottom wall comprises a first section and a second section with different surface loss properties, wherein the movable cover is movable such that the area of the hollow waveguide channel that is covered by the first section and the second section changes with the movement of the movable cover.

### TECHNICAL FIELD

The disclosure relates to a tunable waveguide attenuator. Further, the present disclosure relates to a respective measurement setup, and a respective method for manufacturing the tunable waveguide attenuator.

### BACKGROUND

Although applicable for any type of signals, the present disclosure will mainly be described in conjunction with high frequency electrical signals that comprise frequencies in the GHz range.

In the field of waveguides, signal attenuation is usually realized by introducing attenuating elements, e.g., a thin film of Kapton, into the waveguide channel. However, in such configurations the absorbed energy is converted into thermal energy, which is difficult to dissipate from the waveguide channel. Consequently, such attenuators have a limited attenuation capacity. In the case of Kapton films the maximum attenuation power is limited to about 27 dBm.

Accordingly, there is a need for providing improved attenuators for waveguides.

### SUMMARY

The above stated problem is solved by the features of the independent claims. It is understood, that independent claims of a claim category may be formed in analogy to the dependent claims of another claim category.

Accordingly, it is provided:

A tunable waveguide attenuator comprising a base structure that comprises an input port for coupling to a waveguide for receiving an RF signal, an output port for coupling to a waveguide for outputting the received RF signal, and a bottom wall, a first side wall, and a second side wall, wherein the first side wall and the second side wall are arranged on opposite sides of the bottom wall, and wherein the bottom wall, the first side wall, and the second side wall enclose a hollow waveguide channel on three sides. The tunable waveguide attenuator further comprises a movable cover for the hollow waveguide channel that on a surface facing the bottom wall comprises a first section and a second section with different surface loss properties, wherein the movable cover is movable such that the area of the hollow waveguide channel is covered by the first section and the second section with changing ratio with the movement of the movable cover.

Further, it is provided:

A measurement setup comprising a tunable waveguide attenuator, a RF signal source coupled to an input port of the tunable waveguide attenuator, wherein the tunable waveguide attenuator comprises a base structure that comprises an input port for coupling to a waveguide for receiving an RF signal, an output port for coupling to a waveguide for outputting the received RF signal, and a bottom wall, a first side wall, and a second side wall, wherein the first side wall and the second side wall are arranged on opposite sides of the bottom wall, and wherein the bottom wall, the first side wall, and the second side wall enclose a hollow waveguide channel on three sides, the tunable waveguide attenuator further comprises a movable cover for the hollow waveguide channel that on a surface facing the bottom wall comprises a first section and a second section with different surface loss properties, wherein the movable cover is movable such that the area of the hollow waveguide channel is covered by the first section and the second section with changing ratio with the movement of the movable cover.

Further, it is provided:

A method for manufacturing a tunable waveguide attenuator, the method comprising providing a base structure, and forming on the base structure an input port for coupling to a waveguide for receiving an RF signal, an output port for coupling to a waveguide for outputting the received RF signal, and a bottom wall, a first side wall, and a second side wall, wherein the first side wall and the second side wall are arranged on opposite sides of the bottom wall, and wherein the bottom wall, the first side wall, and the second side wall enclose a hollow waveguide channel on three sides. The method further comprises providing a first section and a second section with different surface loss properties on a movable cover, and movably arranging the movable cover on the hollow waveguide channel such that the area of the hollow waveguide channel is covered by the first section and the second section with changing ratio with the movement of the movable cover.

The present disclosure is based on the finding that attenuators for hollow waveguide structures need to dissipate an increasing amount of heat with increasing signal levels and attenuation levels.

Consequently, the present disclosure provides a tunable waveguide attenuator with such increased heat dissipation capabilities, while at the same time being easily configurable to provide different attenuation levels.

The tunable waveguide attenuator comprises a base structure that forms a hollow waveguide channel and comprises an input port, and an output port for receiving an RF signal and outputting the RF signal after it travels through the hollow waveguide channel. The base structure may comprise a respective front wall for the input port, and a rear wall for the output port, that together with the first side wall, and the second side wall enclose the hollow waveguide channel. The walls may comprise respective openings that form or accommodate the respective input or output ports.

The hollow waveguide channel is formed by a bottom wall or bottom surface, a first side wall, and a second side wall. The first side wall, and the second side wall may be arranged perpendicular to the bottom wall.

The tunable waveguide attenuator further comprises a movable cover. The movable cover serves for covering, and therefore, closing the hollow waveguide channel. The movable cover comprises two different sections at least on the surface that faces the bottom wall. Each one of the two different sections comprises different surface loss properties than the other section. Consequently, each one of the two different sections results in another attenuation being provided by the hollow waveguide channel when the respective section is covering the hollow waveguide channel.

Since the movable cover may be moved over the hollow waveguide channel, the hollow waveguide channel may be covered fully by the first section, fully by the second section, or in part by the first section and in part by the second section.

Depending on the position of the movable cover over the hollow waveguide channel the attenuation may, therefore, be easily configured as required.

Since the two different sections are both provided by the movable cover, the heat dissipation capabilities of the tunable waveguide attenuator are increased, since the material of the movable cover may easily dissipate the thermal energy to the outside of the tunable waveguide attenuator.

Consequently, with the tunable waveguide attenuator according to the present disclosure, it is possible to attenuate signals with higher power levels than with other common waveguide attenuators.

Further embodiments of the present disclosure are subject of the further dependent claims and of the following description, referring to the drawings.

In the following, the dependent claims referring directly or indirectly to claim 1 are described in more detail. For the avoidance of doubt, the features of the dependent claims relating to independent claim 1 can be combined in all variations with each other and the disclosure of the description is not limited to the claim dependencies as specified in the claim set. Further, the features of the dependent claims referring to independent claim 1 may be combined with any of the features of the other independent claims or the dependent claims relating to any one of the other independent claims. In a respective method, respective method steps may perform the function of the respective apparatus elements, and in a respective apparatus, respective apparatus elements may perform the respective method steps.

In an embodiment, which can be combined with all other embodiments mentioned above or below, the surface loss of the first section may be lower than the surface loss of the second section.

The first section may be the section that provides the lowest or almost non-attenuating properties, while the second section may provide the highest required attenuating surface loss properties.

Therefore, by covering the hollow waveguide channel fully with the first section, a non or almost non-attenuating configuration of the tunable waveguide attenuator may be provided. In contrast, by fully covering the tunable waveguide attenuator with the second section, the configuration with the maximum attenuation may be provided.

In a further embodiment, which can be combined with all other embodiments mentioned above or below, in a first maximum position of the movable cover, the hollow waveguide channel may be essentially covered by the first section, in a second maximum position of the movable cover, the hollow waveguide channel may be essentially covered by the second section, and between the first maximum position and the second maximum position of the movable cover, the hollow waveguide channel may be covered partially by the first section, and the second section.

As explained above, the coverage of the hollow waveguide channel by the movable cover may lead to the hollow waveguide channel being fully or at least predominantly, e.g., by 90%, covered by the first section, or the second section.

Between the two maximum positions of the movable cover, the hollow waveguide channel is partially covered by the first section, and the second section.

The possibility of configuring the level of coverage of the hollow waveguide channel by the first section, and the second section allows to easily adapt the level of attenuation provided by tunable waveguide attenuator.

In another embodiment, which can be combined with all other embodiments mentioned above or below, the movable cover may be arranged linearly slideable across the hollow waveguide channel.

The movable cover may be provided such that it may be slid along a single axis or along two axes, especially in a plane that may be parallel to the plane formed by the bottom wall of the hollow waveguide channel.

By allowing the movable cover to slide over the hollow waveguide channel, it is easily possible to adjust the amount of the first section, and the second section that cover the hollow waveguide channel.

In a further embodiment, which can be combined with all other embodiments mentioned above or below, the movable cover may be arranged rotatably slideable across the hollow waveguide channel.

As alternative to a linear movement, the movable cover may be arranged such that it may be rotated around an axis of rotation. In an embodiment, where the movable cover may be rotated, the handling of the movable cover, and therefore, the configuration of the attenuation may be performed easily by a user. For example, a knob may be provided on the movable cover for a user to rotate the movable cover.

In a further embodiment, which can be combined with all other embodiments mentioned above or below, the hollow waveguide channel extends at least one of linearly in a direction of main extension of the hollow waveguide channel, meanderly shaped, and circularly or spirally shaped.

By providing different shapes or structures for the hollow waveguide channel, different needs of different applications may be fulfilled.

For example, a linearly extending hollow waveguide channel may be manufactured easily and may be covered e.g., by a simple rectangular movable cover.

In contrast, a meanderly shaped or mandering hollow waveguide channel may provide an extended length and, therefore, a higher or larger attenuation capability along the hollow waveguide channel may be provided.

A circularly or spirally shaped hollow waveguide channel may provide a compact and easy to use tunable waveguide attenuator. As explained above, a user may easily adjust the attenuation in such an embodiment by rotating the movable cover.

The border between the first section, and the second section may consequently be a straight line, a curved line, a diagonal line with respect to the shape of the movable cover, a non-linear shape, or any arbitrary shape, like an arrow like shape.

In another further embodiment, which can be combined with all other embodiments mentioned above or below, the first section, and the second section may differ from each other by at least one of a material that forms the first section, and the second section, respectively, and a surface roughness, and a surface structure, and a meta material applied to the first section, and the second section, respectively.

The different surface loss properties of the first section, and the second section, may be provided by different means or measures or a combination of different means or measures.

As explained above, the different surface loss properties may e.g., be provided by using different materials for the first section, and the second section, respectively, or by applying a different surface roughness to the first section, and the second section, respectively, or by forming specific surface structures or using meta-materials, like honeycomb structures or gyriod structures. Any combination of these measures is possible.

In another further embodiment, which can be combined with all other embodiments mentioned above or below the first section may comprise gold or silver, or may be formed of gold or silver, and the second section may comprise nickel or aluminum, or may be formed of nickel or aluminum.

Gold or silver as coating or material of the first section each provide a very low attenuation when covering the hollow waveguide channel. In contrast, nickel or aluminum provide a higher attenuation when covering the hollow waveguide channel.

The first section may, therefore, be used to cover the hollow waveguide channel to provide a low attenuation, and the second section may be used to cover the hollow waveguide channel to provide a high attenuation. To provide any attenuation between the lowest and the highest attenuation, the hollow waveguide channel may be partially covered by the first section, and the second section.

In a further embodiment, which can be combined with all other embodiments mentioned above or below, the movable cover may comprise a single carrier wherein the first section, and the second section are formed by respective coatings or structures on the respective surface areas of the carrier, or may comprise a first carrier for the first section, and a second carrier for the second section, wherein the first carrier, and the second carrier are each at least one of covered by respective coatings or structures, and formed of a respective material.

The movable cover may be provided with the different surface loss properties in the first section, and the second section, respectively, by different means.

For example, a single carrier may be provided that forms a base structure for the movable cover. The first section, and the second section, respectively, may be formed on the single carrier by respective coatings or structures that may be formed in the respective areas.

The movable cover may also be formed of two different carriers. Such carriers may be fixed to each other to form the movable cover, for example, by clips or pins, or a combination therefore. Each one of the carries may be formed of a different material, or may be covered with different coatings or structures. A combination of different materials and different coatings or structures is also possible.

The movable cover may, for example, comprise one or multiple carriers made of copper or a copper alloy which may be coated by gold or silver to form the first section, and by aluminum or nickel to form the second section.

The movable cover may in embodiments also comprise one or multiple carriers made of aluminum or an aluminum alloy which may be coated by gold or silver to form the first section, and not covered with any further material to form the second section.

The movable cover may, for example, comprise one or multiple carriers made of plastic which may be coated by gold or silver to form the first section, and by aluminum or nickel to form the second section.

In another further embodiment, which can be combined with all other embodiments mentioned above or below, the first side wall and the second side wall may each comprise at least one of a solid side wall, and a plurality of pins or platform elements, which are spaced apart from each other by a predetermined distance to form a gap waveguide structure.

The first side wall, and/or the second side wall may each be formed e.g., as a gap structure for a waveguide. Such a gap structure allows closing the hollow waveguide channel without establishing a direct contact between the first side wall, and the second side wall on one side, and the movable cover on the other side.

The first side wall, and/or the second side wall may also be formed of a partly solid side wall, especially facing the bottom wall, and a pin or platform element structure, i.e., the gap waveguide structure, especially facing the movable cover.

In another further embodiment, which can be combined with all other embodiments mentioned above or below, the tunable waveguide attenuator may further comprise a guiding structure that accommodates the movable cover such that the movable cover is movably supported with a predetermined distance to the first side wall, and the second side wall.

The guiding structure may e.g. comprise but is not limited to a guiding rail or a guiding grove or slot that may accommodate the movable cover or a respective counterpart of the movable cover.

The guiding structure may also comprise respective end stops or limiting elements that limit the movement of the movable cover, e.g., between two maximum positions.

In another embodiment, which can be combined with all other embodiments mentioned above or below, the tunable waveguide attenuator may further comprise a housing that accommodates the base structure and the movable cover.

The housing serves to protect the single elements of the tunable waveguide attenuator from mechanical and/or electrical influences. Mechanical influences may, e.g., comprise dust particles, and electrical influences may, e.g., comprise electromagnetic signals.

To this end, the housing may be formed of a conductive material or may be covered with a conductive material.

In a further embodiment, which can be combined with all other embodiments mentioned above or below, the tunable waveguide attenuator may further comprise an electric motor that is coupled to the movable cover and controllably moves the movable cover.

The electric motor may comprise any type of electric motor, especially a piezoelectric motor or a stepper motor. The electric motor may be provided within the housing or outside the housing.

With the electric motor, an automated control of the tunable waveguide attenuator is possible. This not only simplifies control of the tunable waveguide attenuator, but also allows using the tunable waveguide attenuator in automated test procedures that require setting different attenuation levels.

The electric motor may be configured to move the movable cover from a first to a second maximum position, the first position providing the lowest attenuation, and the second position providing the highest attenuation, or vice versa.

In another further embodiment, which can be combined with all other embodiments mentioned above or below, the tunable waveguide attenuator may further comprise a cooling structure that dissipates heat at least from the movable cover.

The cooling structure may e.g., comprise cooling channels incorporated into the movable cover, and/or any component of the base structure. Air or a respective cooling liquid may be pumped through such cooling channels.

The cooling structure may also comprise ribs or fins, and optionally or alternatively, a fan. The cooling structure may also comprise a heat pipe arrangement or a Peltier element.

Any combination of the above is also possible.

### BRIEF DESCRIPTION OF THE DRAWINGS

For a more complete understanding of the present disclosure and advantages thereof, reference is now made to the following description taken in conjunction with the accompanying drawings. The disclosure is explained in more detail below using exemplary embodiments which are specified in the schematic figures of the drawings, in which:

FIG. 1 shows a schematic diagram of an embodiment of a tunable waveguide attenuator according to the present disclosure;

FIG. 2 shows a schematic diagram of possible embodiments of a movable cover according to the present disclosure;

FIG. 3 shows a schematic diagram of another embodiment of a tunable waveguide attenuator according to the present disclosure;

FIG. 4 shows a schematic diagram of the embodiment of a tunable waveguide attenuator of FIG. 3 with the movable cover in different positions;

FIG. 5 shows a schematic diagram of another embodiment of a tunable waveguide attenuator according to the present disclosure;

FIG. 6 shows a schematic diagram of the embodiment of a tunable waveguide attenuator of FIG. 5 with the movable cover in different positions;

FIG. 7 shows a schematic diagram of another embodiment of a tunable waveguide attenuator according to the present disclosure;

FIG. 8 shows a schematic diagram of an embodiment of a measurement setup according to the present disclosure; and

FIG. 9 shows a flow diagram of an embodiment of a method according to the present disclosure.

In the figures like reference signs denote like elements unless stated otherwise.

### DETAILED DESCRIPTION OF THE DRAWINGS

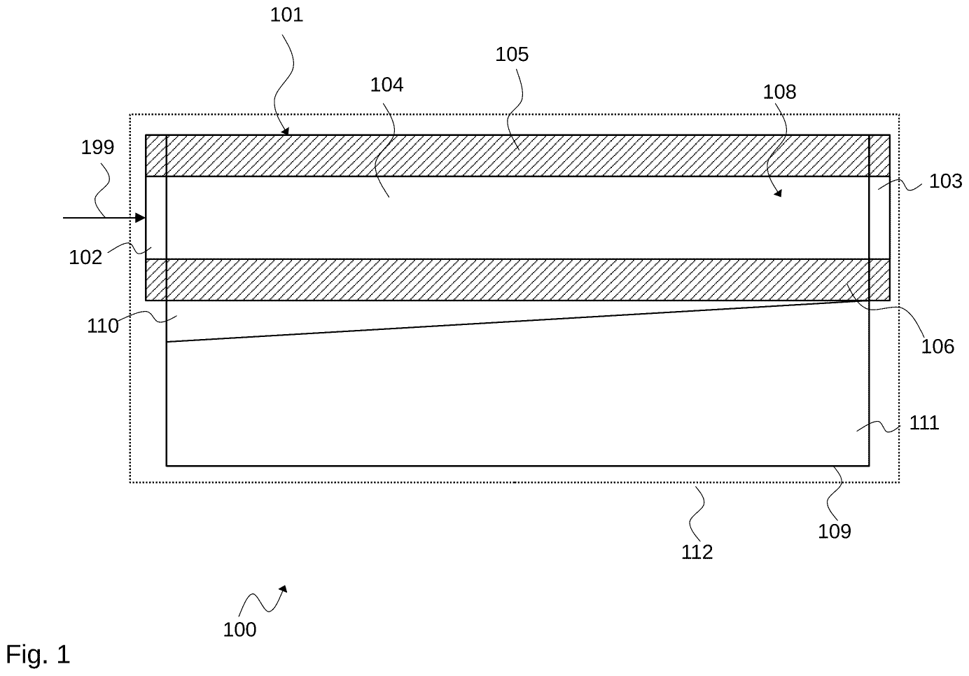

FIG. 1 shows a tunable waveguide attenuator 100. The tunable waveguide attenuator 100 comprises a base structure 101 that comprises an input port 102, an output port 103, a bottom wall 104, a first side wall 105, and a second side wall 106. The tunable waveguide attenuator 100 further comprises movable cover 109. The input port 102 serves for coupling to a waveguide for receiving an RF signal 199, and the output port 103 serves for coupling to a waveguide for outputting the received RF signal. The first side wall 105, and the second side wall 106 are arranged on opposite sides of the bottom wall 104. The bottom wall 104, the first side wall 105, and the second side wall 106 enclose a hollow waveguide channel 108 on three sides or form a hollow waveguide channel 108. The movable cover 109 covers the hollow waveguide channel 108, and comprises on a surface facing the bottom wall 104 a first section 110 and a second section 111. Each one of the first section 110 and the second section 111 comprises different surface loss properties. The movable cover 109 is movable such that the area of the hollow waveguide channel 108 is covered by the first section 110 and the second section 111 with changing ratio with the movement of the movable cover 109. An optional housing 112 is shown that may surround the tunable waveguide attenuator 100. The explanations provided herein for any one of the embodiments of the tunable waveguide attenuator apply mutatis mutandis to the tunable waveguide attenuator 100.

The tunable waveguide attenuator 100 is shown in a top view, and it can be seen that the two sections 110, 111 of the movable cover 109 are divided by a linear boundary line. The movable cover 109 may move from a first maximum position (as shown) to a second maximum position. In the tunable waveguide attenuator 100, in the first maximum position, the movable cover 109 is moved down such that the first section 110 fully covers the hollow waveguide channel 108. In the second maximum position, the movable cover 109 is moved up such that the second section 111 fully covers the hollow waveguide channel 108. Between the first maximum position and the second maximum position of the movable cover 109, the hollow waveguide channel 108 is covered partially by the first section 110, and the second section 111.

In order to provide a tunable attenuation, the surface loss of the first section 110 may be lower than the surface loss of the second section 111. The first section 110, and the second section 111 may, e.g., differ from each other at least one of by a material that forms the first section 110, and the second section 111, respectively, by a surface roughness, by a surface structure, and by a meta-material applied to the first section 110, and the second section 111, respectively.

The first section 110 may, e.g., comprise gold or silver, or may be formed of gold or silver. The second section 111 may comprise nickel or aluminum, or may be formed of nickel or aluminum.

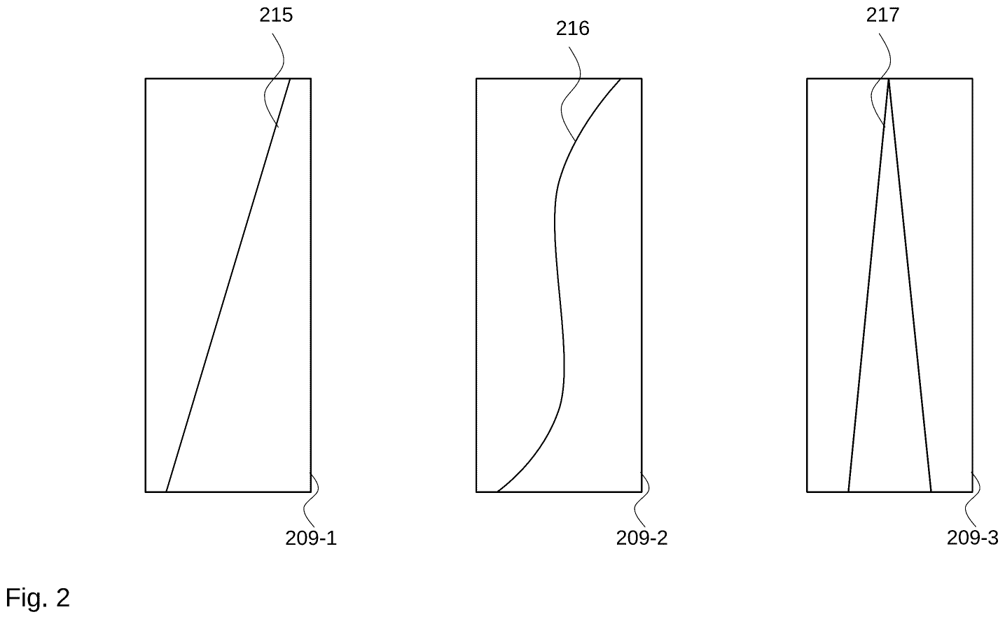

FIG. 2 shows three possible movable covers 209-1, 209-2, 209-3. While the movable covers 209-1, 209-2, 209-3 comprise a square shape, it is understood, that in other embodiments, the movable covers may also comprise any other shape, like a round shape. The movable covers 209-1, 209-2, 209-3 may be used, e.g., with the tunable waveguide attenuator 100 of FIG. 1 or any other adequate embodiment of the tunable waveguide attenuator.

The movable cover 209-1 comprises a straight or linear boundary line 215 between the first section and the second section. The movable cover 209-2 comprises a curved boundary line 216 between the first section and the second section. The movable cover 209-3 comprises an arrow shaped boundary line 217 between the first section and the second section. Any other shapes are also possible.

Any embodiment of the movable cover disclosed herein may comprise a single carrier. With such a single carrier, the first section, and the second section may be formed by respective coatings or structures on the respective surface areas of the carrier. In other embodiments, the movable cover may comprise a first carrier for the first section, and a second carrier for the second section. The first carrier, and the second carrier may each at least one of be covered by respective coatings or structures, and formed of a respective material.

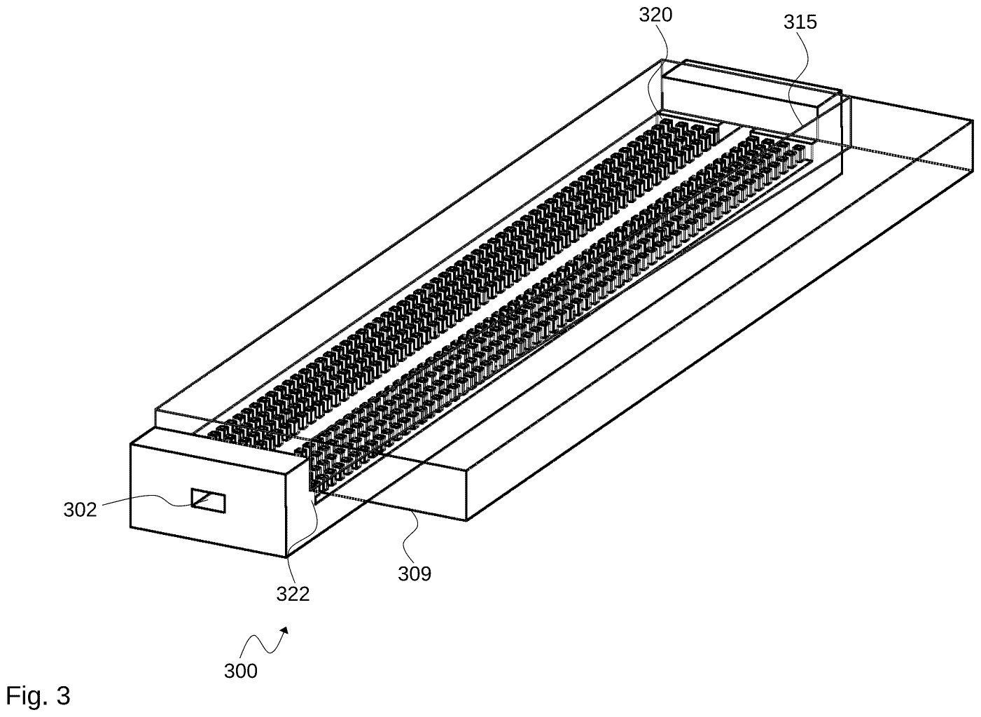

FIG. 3 shows a tunable waveguide attenuator 300 in a perspective view. The tunable waveguide attenuator 300 is based on the tunable waveguide attenuator 100. Therefore, the tunable waveguide attenuator 300 comprises a base structure that comprises an input port 302, an output port, a bottom wall, a first side wall, and a second side wall. The tunable waveguide attenuator 300 further comprises movable cover 309 with a linear boundary line 315 between a first and a second section. The explanations provided herein for any one of the embodiments of the tunable waveguide attenuator apply mutatis mutandis to the tunable waveguide attenuator 300.

In the tunable waveguide attenuator 300, the first side wall, and the second side wall do not comprise solid material. Instead, the first side wall, and the second side wall are each implemented as gap structure with a plurality of pins 320. With such a gap structure, the height of the single pins 320 may be adapted such that the movable cover 309 may be slid over the hollow waveguide channel without mechanically contacting the single pins 320.

In the position shown in FIG. 3, the movable cover 309 is in the first maximum position and the first section of the movable cover 309 covers the hollow waveguide channel. Further, the movable cover 309 is supported by a guide or guiding rail 322. This guiding rail 322 may also be used to set the distance between the movable cover 309 and the top of the first side wall, and the second side wall.

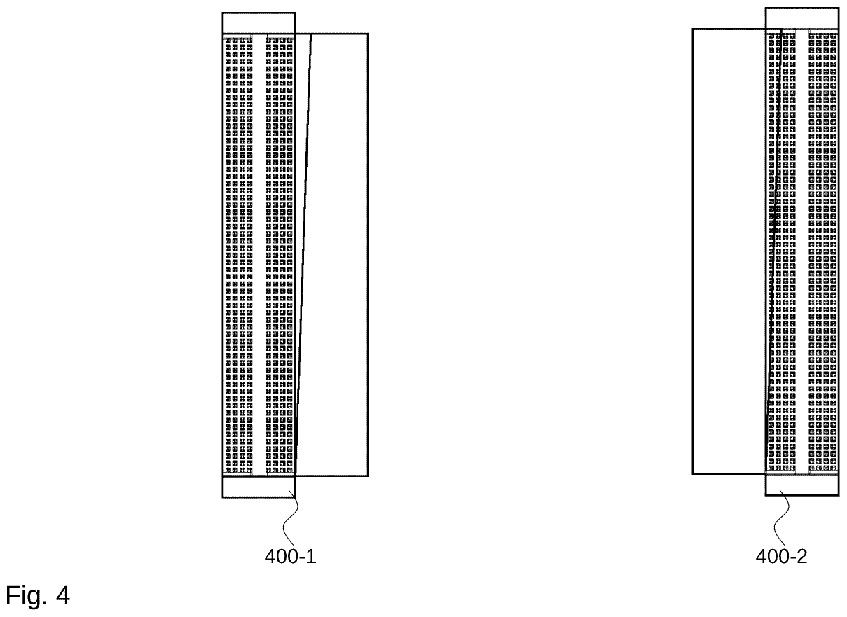

FIG. 4 shows tunable waveguide attenuators 400-1, 400-2, which show the tunable waveguide attenuator 300 with the movable cover in the first maximum position and the second maximum position.

As can be seen, in the tunable waveguide attenuator 400-1, the movable cover is in the right-most position, i.e., the first maximum position. In the tunable waveguide attenuator 400-2, the movable cover is in the left-most position, i.e., the second maximum position. In the second maximum position, the hollow waveguide channel is fully covered by the second section.

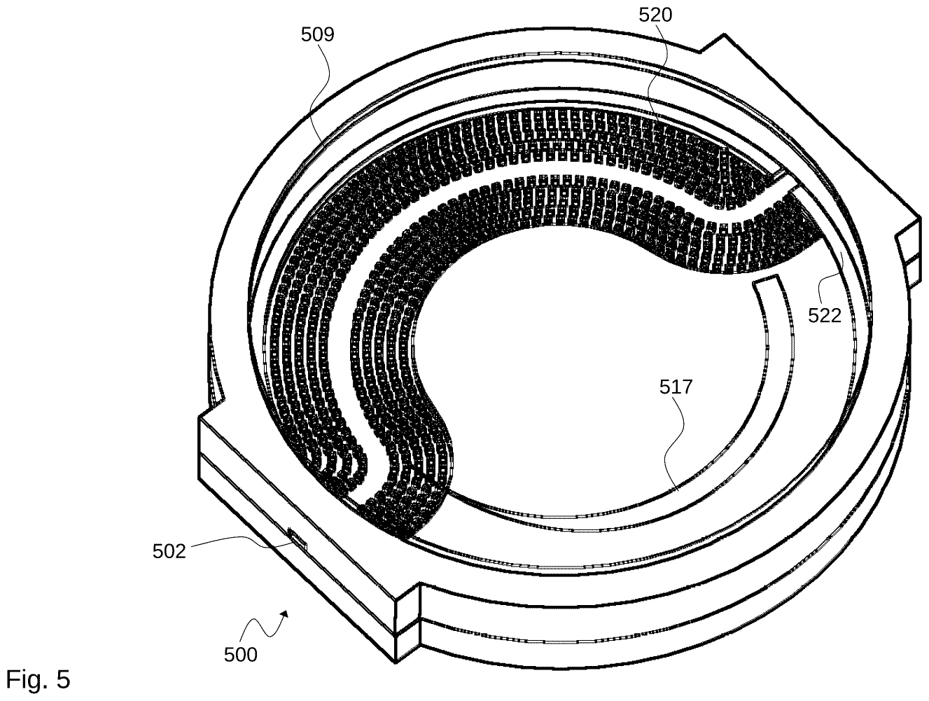

FIG. 5 shows a tunable waveguide attenuator 500. The tunable waveguide attenuator 500 is based on the tunable waveguide attenuator 100. Therefore, the tunable waveguide attenuator 500 comprises a base structure that comprises an input port 502, an output port, a bottom wall, a first side wall, and a second side wall. The tunable waveguide attenuator 500 further comprises movable cover 509 with a boundary line 517 that is formed like a bend arrow and delimits the second section (within the arrow) from the first section (outside the arrow). The explanations provided herein for any one of the embodiments of the tunable waveguide attenuator apply mutatis mutandis to the tunable waveguide attenuator 500.

In contrast to the square-shaped tunable waveguide attenuators, the tunable waveguide attenuator 500 comprises a round shape or circumference. It can be seen that the hollow waveguide channel is delimited by a first side wall, and a second side wall that are both formed as a gap structure of a plurality of pins 520. The movable cover 509 is supported by a guide rail 522.

In the tunable waveguide attenuator 500, the movable cover 509 is in the first maximum position, i.e., the hollow waveguide channel is fully covered by the first section.

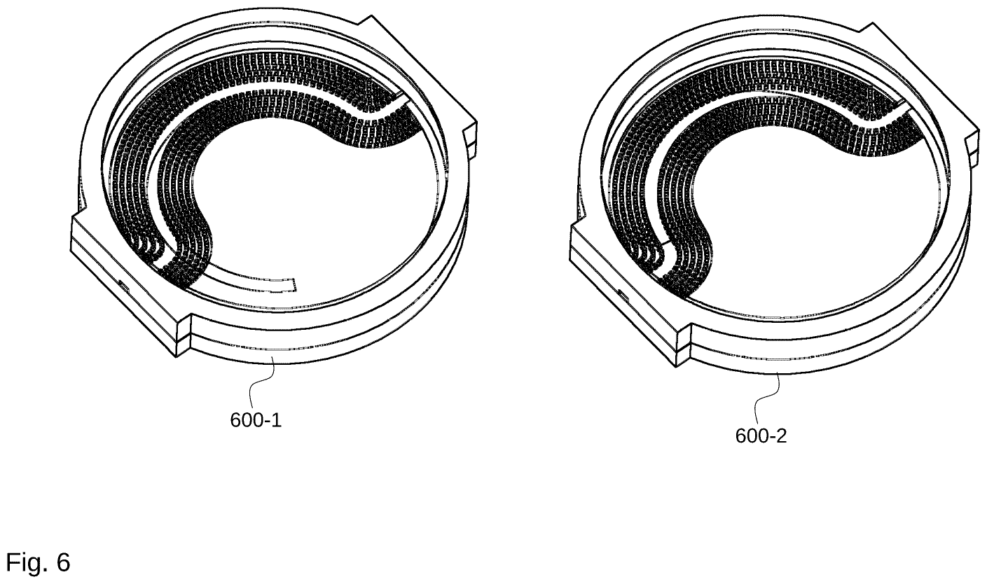

FIG. 6 shows tunable waveguide attenuators 600-1, 600-2, which show the tunable waveguide attenuator 500 with the movable cover 509 in the first maximum position and the second maximum position.

As can be seen, in the tunable waveguide attenuator 600-1, the movable cover is in the first maximum position, where no part of the arrow shaped second section covers the hollow waveguide channel. In the tunable waveguide attenuator 600-2, the movable cover is in the second maximum position, where the arrow shaped second section is fully introduced in the hollow waveguide channel.

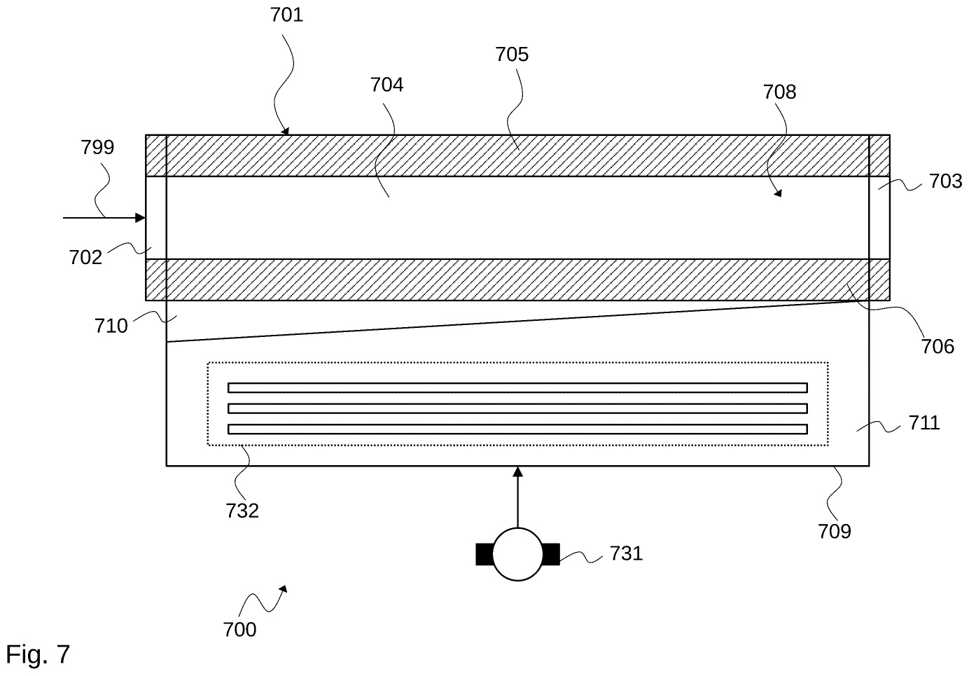

FIG. 7 shows a tunable waveguide attenuator 700. The tunable waveguide attenuator 700 is based on the tunable waveguide attenuator 100. Therefore, the tunable waveguide attenuator 700 comprises a base structure 701 that comprises an input port 702, an output port 703, a bottom wall 704, a first side wall 705, and a second side wall 706. The tunable waveguide attenuator 700 further comprises movable cover 709. The input port 702 serves for coupling to a waveguide for receiving an RF signal 799, and the output port 703 serves for coupling to a waveguide for outputting the received RF signal. The first side wall 705, and the second side wall 706 are arranged on opposite sides of the bottom wall 704. The bottom wall 704, the first side wall 705, and the second side wall 706 enclose a hollow waveguide channel 708 on three sides or form a hollow waveguide channel 708. The movable cover 709 covers the hollow waveguide channel 708, and comprises on a surface facing the bottom wall 704 a first section 710 and a second section 711. Each one of the first section 710 and the second section 711 comprises different surface loss properties. The movable cover 709 is movable such that the area of the hollow waveguide channel 708 is covered by the first section 710 and the second section 711 with changing ratio with the movement of the movable cover 709. An optional housing 712 is shown that may surround the tunable waveguide attenuator 700. The explanations provided herein for any one of the embodiments of the tunable waveguide attenuator apply mutatis mutandis to the tunable waveguide attenuator 700.

The tunable waveguide attenuator 700 further comprises an electric motor 731 that is mechanically coupled to the movable cover 709 and may controllably move the movable cover 709 to any position between the first maximum position to the second maximum position.

Further, the tunable waveguide attenuator 700 comprises a cooling arrangement 732 in the form of fins or ribs. It is understood, that in embodiments, the electric motor 731, and/or the cooling arrangement 732 may be omitted.

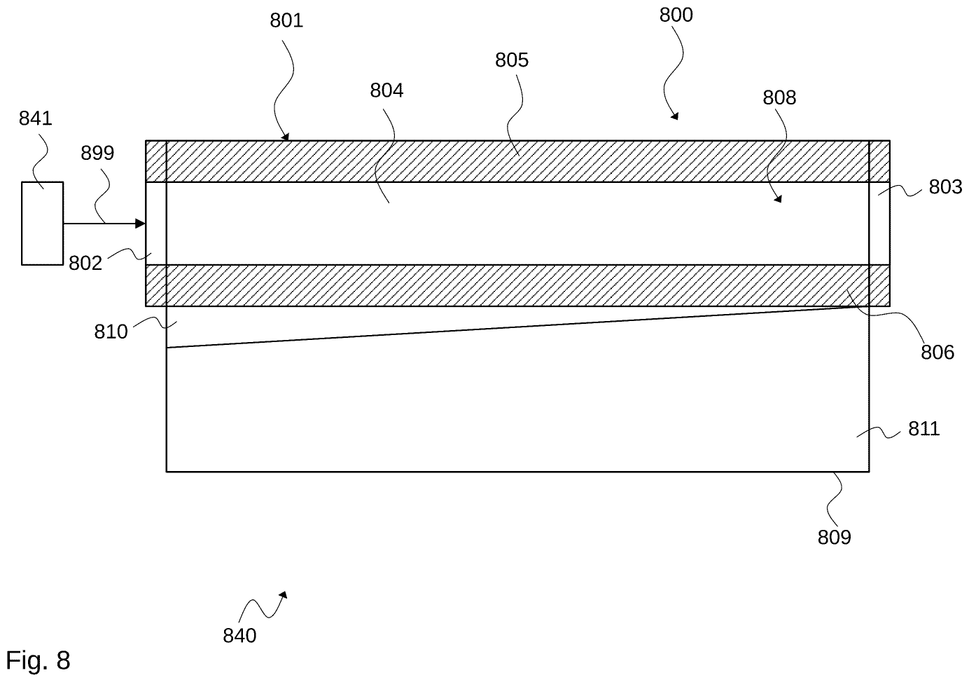

FIG. 8 shows a measurement setup 840. The measurement setup 840 comprises a tunable waveguide attenuator 800. The tunable waveguide attenuator 800 is based on the tunable waveguide attenuator 100. Therefore, the tunable waveguide attenuator 800 comprises a base structure 801 that comprises an input port 802, an output port 803, a bottom wall 804, a first side wall 805, and a second side wall 806. The tunable waveguide attenuator 800 further comprises movable cover 809. The input port 802 serves for receiving an RF signal 899, and the output port 803 serves for coupling to a waveguide for outputting the received RF signal. The the first side wall 805, and the second side wall 806 are arranged on opposite sides of the bottom wall 804. The bottom wall 804, the first side wall 805, and the second side wall 806 enclose a hollow waveguide channel 808 on three sides or form a hollow waveguide channel 808. The movable cover 809 covers the hollow waveguide channel 808, and comprises on a surface facing the bottom wall 804 a first section 810 and a second section 811. Each one of the first section 810 and the second section 811 comprises different surface loss properties. The movable cover 809 is movable such that the area of the hollow waveguide channel 808 is covered by the first section 810 and the second section 811 with changing ratio with the movement of the movable cover 809. The explanations provided herein for any one of the embodiments of the tunable waveguide attenuator apply mutatis mutandis to the tunable waveguide attenuator 800.

The tunable waveguide attenuator 800 in the measurement setup 840 is coupled to an RF signal source 841 that provides the RF signal 899 to the tunable waveguide attenuator 800.

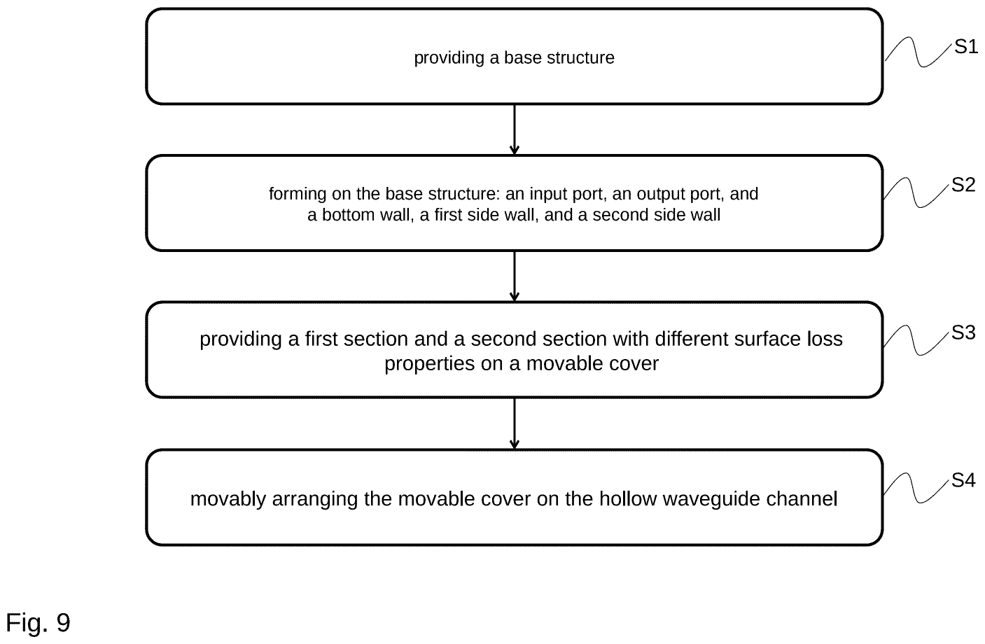

FIG. 9 shows a flow diagram of a method for manufacturing a tunable waveguide attenuator. The method comprises providing S1 a base structure, and forming S2 on the base structure an input port for coupling to a waveguide for receiving an RF signal, an output port for coupling to a waveguide for outputting the received RF signal, and a bottom wall, a first side wall, and a second side wall, wherein the first side wall and the second side wall are arranged on opposite sides of the bottom wall, and wherein the bottom wall, the first side wall, and the second side wall enclose a hollow waveguide channel on three sides. The method further comprises providing S3 a first section and a second section with different surface loss properties on a movable cover, and movably S4 arranging the movable cover on the hollow waveguide channel such that the area of the hollow waveguide channel is covered by the first section and the second section with changing ratio with the movement of the movable cover.

The movable cover may be arranged on the hollow waveguide channel such that at least one of in a first maximum position of the movable cover, the hollow waveguide channel is essentially covered by the first section, in a second maximum position of the movable cover, the hollow waveguide channel is essentially covered by the second section, and between the first maximum position and the second maximum position of the movable cover, the hollow waveguide channel is covered partially by the first section, and the second section.

The movable cover may be arranged linearly slideable across the hollow waveguide channel. Alternatively, the movable cover may be arranged rotatably slideable across the hollow waveguide channel.

The hollow waveguide channel may be formed to extend at least one of linearly in a direction of main extension of the hollow waveguide channel, meanderly shape, and circularly or spirally shaped.

The first side wall and the second side wall may be formed or manufactured each to comprise at least one of a solid side wall, and a plurality of pins or platform elements, which are spaced apart from each other by a predetermined distance to form a gap waveguide structure.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

The abstract of the disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

LIST OF REFERENCE SIGNS

| | |
|---|---|
| 100, 300, 400-1, 400-2, 500 | tunable waveguide attenuator |
| 600-1, 600-2, 700 | tunable waveguide attenuator |
| 101, 701 | base structure |
| 102, 302, 502, 702 | input port |
| 103, 703 | output port |
| 104, 704 | bottom wall |
| 105, 705 | first side wall |
| 106, 706 | second side wall |
| 108, 708 | hollow waveguide channel |
| 109, 209-1, 209-2, 209-3, 309, 509, 709 | movable cover |
| 110, 710 | first section |
| 111, 711 | second section |
| 112 | housing |
| 215, 315 | linear boundary line |
| 216 | meanderly shaped boundary line |
| 217, 517 | free shape boundary line |
| 320, 520 | pin |
| 322, 522 | guiding structure |
| 731 | electric motor |
| 732 | cooling structure |
| 840 | measurement setup |
| 841 | RF signal source |
| 199, 799, 899 | RF signal |
| S1-S4 | method steps |

1. A tunable waveguide attenuator comprising:
a base structure that comprises:
an input port for coupling to a waveguide for receiving an RF signal;
an output port for coupling to a waveguide for outputting the received RF signal; and
a bottom wall, a first side wall, and a second side wall, wherein the first side wall and the second side wall are arranged on opposite sides of the bottom wall, and wherein the bottom wall, the first side wall, and the second side wall enclose a hollow waveguide channel on three sides;
the tunable waveguide attenuator further comprising:
a movable cover for the hollow waveguide channel that on a surface facing the bottom wall comprises a first section and a second section with different surface loss properties;
wherein the movable cover is movable such that the area of the hollow waveguide channel is covered by the first section and the second section with a changing ratio with the movement of the movable cover.

2. The tunable waveguide attenuator according to claim 1, wherein the surface loss of the first section is lower than the surface loss of the second section.

3. The tunable waveguide attenuator according to claim 1, wherein:
in a first maximum position of the movable cover, the hollow waveguide channel is essentially covered by the first section;
in a second maximum position of the movable cover, the hollow waveguide channel is essentially covered by the second section; and
between the first maximum position and the second maximum position of the movable cover, the hollow waveguide channel is covered partially by the first section, and the second section.

4. The tunable waveguide attenuator according to claim 1, wherein the movable cover is arranged linearly slideable across the hollow waveguide channel.

5. The tunable waveguide attenuator according to claim 1, wherein the movable cover is arranged rotatably slideable across the hollow waveguide channel.

6. The tunable waveguide attenuator according to claim 1, wherein the hollow waveguide channel extends at least one of:
linearly in a direction of main extension of the hollow waveguide channel;
meanderly shaped; or
circularly or spirally shaped.

7. The tunable waveguide attenuator according to claim 1, wherein the first section and the second section differ from each other by at least one of:
a material that forms the first section, and the second section, respectively;
a surface roughness;
a surface structure; or
a meta material applied to the first section, and the second section, respectively.

8. The tunable waveguide attenuator according to claim 1, wherein:
the first section comprises gold or silver, or is formed of gold or silver; and
the second section comprises nickel or aluminum, or is formed of nickel or aluminum.

9. The tunable waveguide attenuator according to claim 1, wherein the movable cover at least one of:
comprises a single carrier, wherein the first section and the second section are formed by respective coatings or structures on respective surface areas of the carrier; or
comprises a first carrier for the first section and a second carrier for the second section, wherein the first carrier and the second carrier are each at least one of covered by respective coatings or structures, and formed of a respective material.

10. The tunable waveguide attenuator according to claim 1, wherein the first side wall and the second side wall each comprises at least one of:
a solid side wall; or
a plurality of pins or platform elements, which are spaced apart from each other by a predetermined distance to form a gap waveguide structure.

11. The tunable waveguide attenuator according to claim 1, further comprising a guiding structure that accommodates the movable cover such that the movable cover is movably supported with a predetermined distance to the first side wall, and the second side wall.

12. The tunable waveguide attenuator according to claim 1, further comprising a housing that accommodates the base structure and the movable cover.

13. The tunable waveguide attenuator according to claim 1, further comprising an electric motor that is coupled to the movable cover and controllably moves the movable cover.

14. The tunable waveguide attenuator according to claim 1, further comprising a cooling structure that dissipates heat at least from the movable cover.

15. A measurement setup comprising:
a tunable waveguide attenuator; and
a RF signal source coupled to an input port of the tunable waveguide attenuator;
wherein the tunable waveguide attenuator comprises a base structure that comprises:
an input port for coupling to a waveguide for receiving an RF signal;
an output port for coupling to a waveguide for outputting the received RF signal; and
a bottom wall, a first side wall, and a second side wall, wherein the first side wall and the second side wall are arranged on opposite sides of the bottom wall, and wherein the bottom wall, the first side wall, and the second side wall enclose a hollow waveguide channel on three sides;
the tunable waveguide attenuator further comprising:
a movable cover for the hollow waveguide channel that on a surface facing the bottom wall comprises a first section and a second section with different surface loss properties;
wherein the movable cover is movable such that the area of the hollow waveguide channel is covered by the first section and the second section with a changing ratio with the movement of the movable cover.

16. The measurement setup of claim 15 further comprising a RF signal sink coupled to the output port of the tunable waveguide attenuator.

17. A method for manufacturing a tunable waveguide attenuator, the method comprising:
providing a base structure, and forming on the base structure:
an input port for coupling to a waveguide for receiving an RF signal;
an output port for coupling to a waveguide for outputting the received RF signal; and
a bottom wall, a first side wall, and a second side wall, wherein the first side wall and the second side wall are arranged on opposite sides of the bottom wall, and wherein the bottom wall, the first side wall, and the second side wall enclose a hollow waveguide channel on three sides;
providing a first section and a second section with different surface loss properties on a movable cover; and
movably arranging the movable cover on the hollow waveguide channel such that the area of the hollow waveguide channel is covered by the first section and the second section with a changing ratio with the movement of the movable cover.

18. The method according to claim 17, wherein the movable cover is arranged on the hollow waveguide channel such that:
in a first maximum position of the movable cover, the hollow waveguide channel is essentially covered by the first section;
in a second maximum position of the movable cover, the hollow waveguide channel is essentially covered by the second section; and
between the first maximum position and the second maximum position of the movable cover, the hollow waveguide channel is covered partially by the first section, and the second section;
wherein at least one of:
the movable cover is arranged linearly slideable across the hollow waveguide channel; or
the movable cover is arranged rotatably slideable across the hollow waveguide channel.

19. The method according to claim 17, wherein the hollow waveguide channel is formed to extend at least one of:
linearly in a direction of main extension of the hollow waveguide channel;
meanderly shaped; or
circularly or spirally shaped.

20. The method according to claim 17, wherein the first side wall and the second side wall are each formed to comprise at least one of:
a solid side wall; or
a plurality of pins or platform elements, which are spaced apart from each other by a predetermined distance to form a gap waveguide structure.
